(19) United States
(12) Patent Application Publication
(10) Pub. No.: US 2010/0052660 A1
(43) Pub. Date: Mar. 4, 2010

(54) PORTABLE ELECTRONIC DEVICE WITH HALL SENSOR

(75) Inventor: Min-Sheng Wang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication Systems, Inc., Tu-Cheng City (TW)

(21) Appl. No.: 12/464,966

(22) Filed: May 13, 2009

(30) Foreign Application Priority Data
Aug. 29, 2008 (CN) 200810304311.1

(51) Int. Cl. H01L 43/06; H04M 1/00

(52) U.S. Cl. 324/207.2; 455/575.4

(57) ABSTRACT

A portable electronic device comprises a first body having a magnet member mounted thereon; a second body slidably assembled on the first body and including a Hall sensor mounted thereon. The magnet member acts on the Hall sensor with the first body is moved relative to the second body, thereby switching the portable electronic device to a work mode when the Hall sensor faces the magnet member or a power save mode when the Hall sensor is spaced away from the magnet member.

### BACKGROUND

1. Technical Field

The present disclosure generally relates to portable electronic devices, particularly to a portable electronic device with a Hall sensor.

2. Description of Related Art

With the development of wireless communication and information processing technologies, foldable electronic devices such as mobile phones and personal digital assistants (PDAs) are now in widespread use, and consumers may now enjoy the full convenience of high technology products almost anytime and anywhere. Foldable electronic devices are particularly favored by a wide range of consumers because of their small size, novel design and ease of use.

The foldable electronic device such as mobile phone generally includes a cover portion and a body portion. The cover portion and the body portion are rotatably interconnected by a hinge, thus allowing the mobile phone to be switched between an in-use position and a closed position. When the cover portion is opened relative to the body portion, the mobile phone is automatically switched to a work mode.

The modes changes of the foldable electronic device are accomplished by a device controlling a servo system to be conducted or be shut off. The device usually includes a Hall sensor and a magnet. The Hall sensor is a transducer, whose output voltage varies with magnetic fields. Due to a change of the position relationship between the Hall sensor and the magnet, the Hall sensor detects the magnetic field of the magnet and inputs information to activate the servo system. Referring to FIGS. 5 and 6, a conventional mobile phone 10 is shown. The mobile phone 10 includes a body portion 12, a cover portion 14 and a hinge assembly 16. The hinge assembly 16 is rotatably connected to the body portion 12 and the cover portion 14. The body portion 12 has a printed circuit board 120 positioned therein. The printed circuit board 120 has a servo system electronically connected to a Hall sensor 122. The cover portion 14 includes a magnet 142 corresponding to the Hall sensor 122. The magnet 142 includes an S pole 1424 and an N pole 1422. When the cover portion 14 is closed relative to the body portion 12, the S pole 1424 of the magnet 142 is adjacent to the Hall sensor 122.

When a user opens the mobile phone 10, the cover portion 14 with the magnet 142 is moved away from the body portion 12. Accordingly, the Hall sensor 122 is moved away from the S pole 1424 of the magnet 142 towards the N pole 1422. The Hall sensor 122 then activates the servo system of the printed circuit board 120 to switch the mobile phone 10 to the work mode. When the cover portion 14 is moved towards the body portion 12, the Hall sensor 122 faces the S pole 1424 of the magnet 142. The Hall sensor 122 will switch the servo system off, and allow the mobile phone 10 to be in a power saver mode. Although the above device may realize the control for the work mode of the mobile phone, the magnet 142 is an added component and occupies a space in the cover portion 14. Such cover portion 14 does not satisfy requirements in miniaturization of mobile phones.

Therefore, there is room for improvement within the art.

### BRIEF DESCRIPTION OF THE DRAWINGS

Many aspects of the portable electronic device with the Hall sensor can be better understood with reference to the following drawings. The components in the drawings are not necessarily drawn to scale, the emphasis instead being placed upon clearly illustrating the principles of the present portable electronic device with a Hall sensor. Moreover, in the drawings, like reference numerals designate corresponding parts throughout the several views:

FIG. 1 is an isometric view of a portable electronic device of an embodiment.

FIG. 2 is an isometric view of the embodiment of the portable electronic device in an opened state shown in FIG. 1.

FIG. 3 is a cross-section view of the portable electronic device in an opened state shown in FIG. 2.

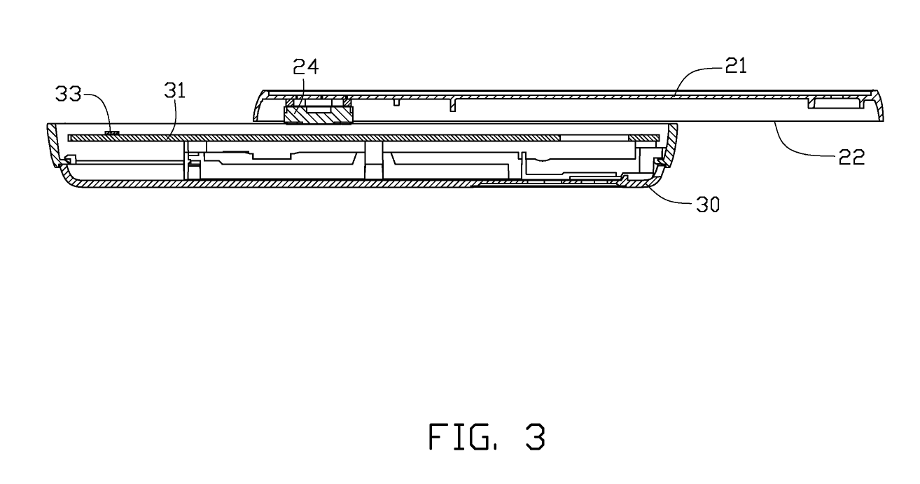

FIG. 4 is a cross-section view of the portable electronic device in an closed state.

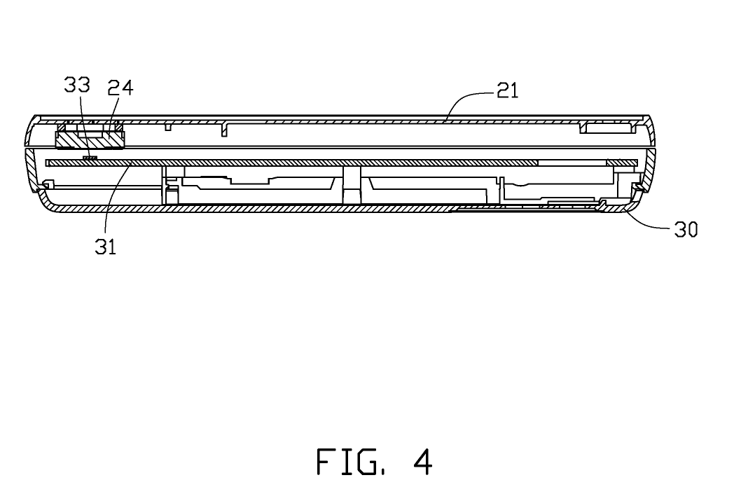

FIG. 5 is a conventional view of a mobile phone with a Hall sensor and a magnet.

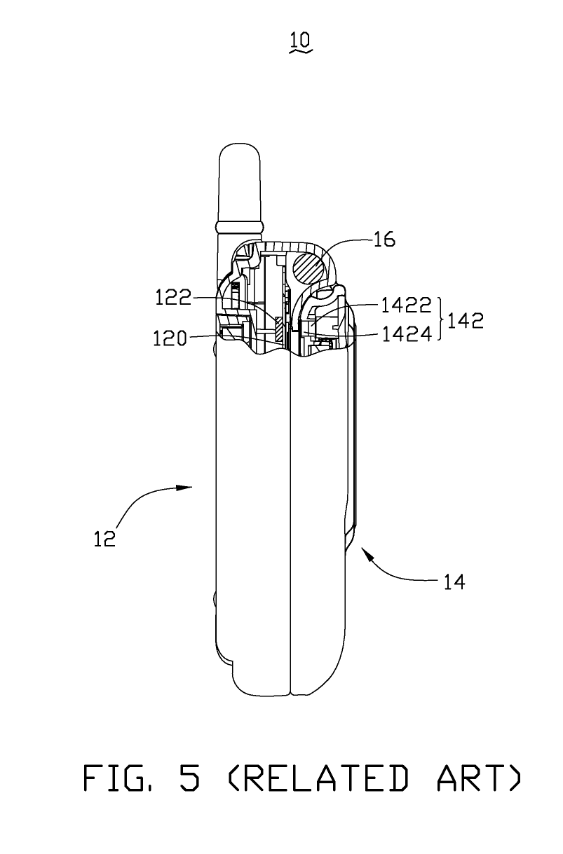

FIG. 6 is similar to FIG. 5, showing the conventional mobile phone as opened.

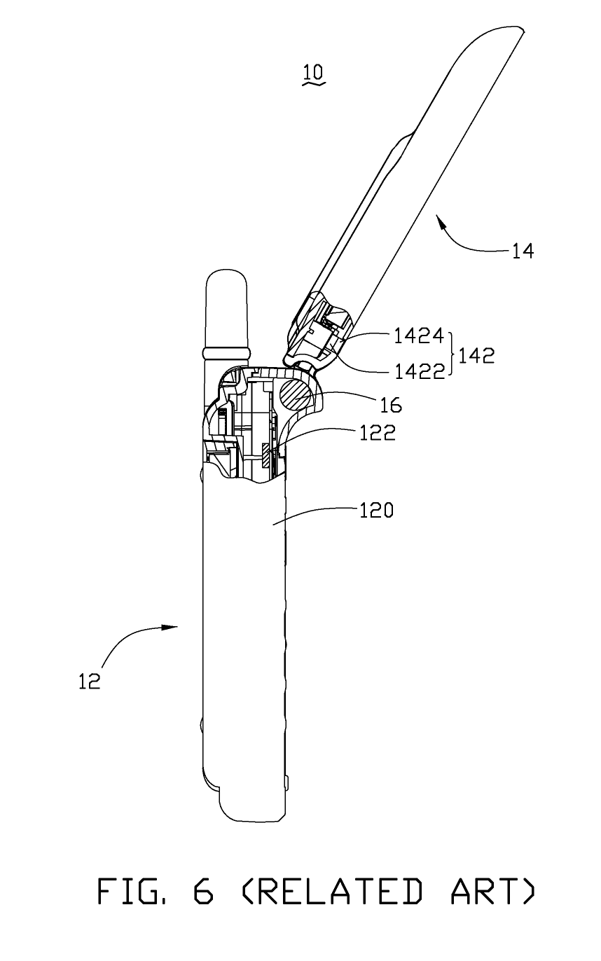

### DETAILED DESCRIPTION OF THE INVENTION

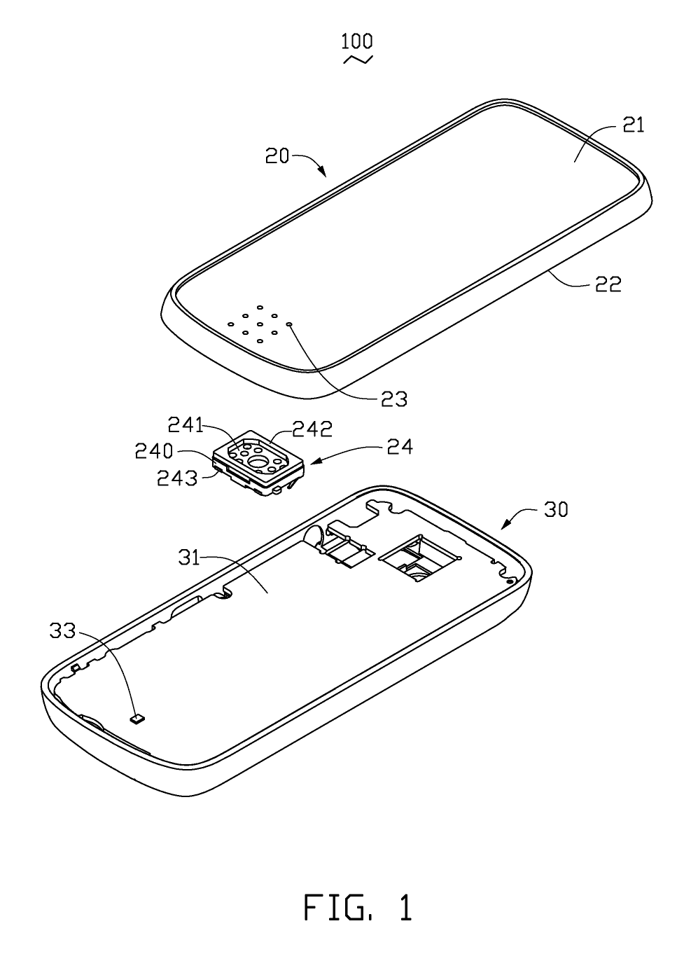

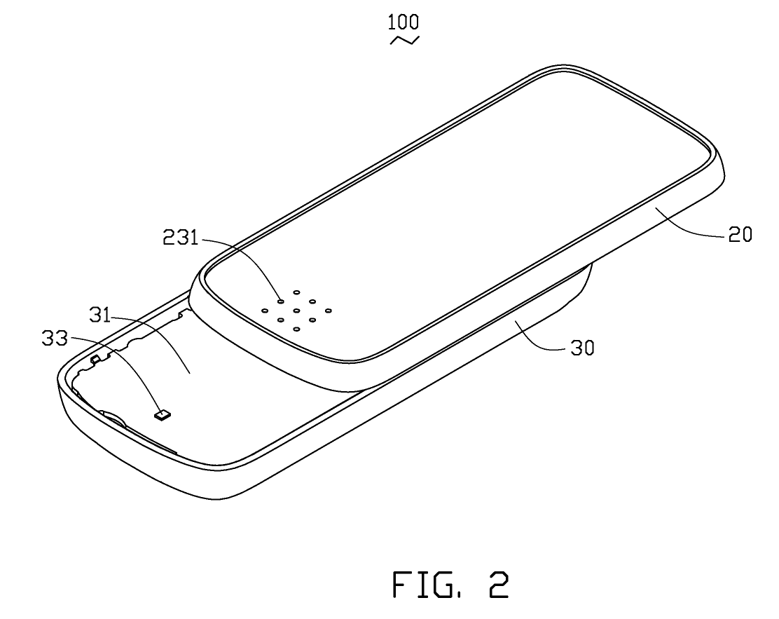

Referring to FIGS. 1 and 2, a portable electronic device such as a sliding type mobile phone 100, in one illustrated embodiment, includes a first body 20 having a magnet member 24 mounted thereon, a second body 30 having a Hall sensor 33 mounted thereon, and a sliding mechanism (not shown) connecting the first body 20 to the second body 30. The second body 30 is slidably assembled on the first body 20 by the sliding mechanism.

The first body 20 is a substantially rectangular structure including an upper wall 21, a lower wall 22 opposite to the upper wall 21, and a magnet member 24. The upper wall 21 includes a sound hall portion 23 defining a plurality of holes 231 therein.

The magnet member 24, in an exemplary embodiment, may be a speaker secured in the first body 20. The magnet member 24 includes a main body 240 and a sound-absorbing part 242 attached to the main body 240. The main body 240 includes a first wall 241 and a second wall 243 opposite to the first wall 241. The sound-absorbing part 242 is frame shaped and made of foam. The sound-absorbing part 242 has about the same dimensions as the sound hall portion 23.

The second body 30 includes a circuit board 31 and a Hall sensor 33 attached to the circuit board 31. The second body 30 further includes a matching surface (not shown) matching with the lower wall 22.

The Hall sensor 33 controls the work mode of the sliding type mobile phone 100 by detecting the magnetic field of the magnet member 24 so as to activate or shut off the circuit board 31. When the Hall sensor 33 faces to the magnet member 24, the Hall sensor 33 may detect the magnetic field of the magnet member 24 and send a command to the circuit board 31 to turn off the background lights. When the Hall sensor 33 is moved away from the magnet member 24, the Hall sensor 33 does not detect any magnetic field, thus sending a command to the circuit board 31 to turn on the background lights and enable information input.

When the magnet member 24 is assembled in the first body 20, the sound-absorbing part 242 is aligned with and faces the sound hall portion 23. Then the sound-absorbing part 242 is adhered to the sound hall portion 23, thereby securing the magnet member 24 in the first body 20. Finally, the Hall sensor 33 connects to the circuit board 31 and faces to the magnet member 24 when the sliding type mobile phone 100 is in closed state.

In use, when the sliding type mobile phone 100 is closed, the magnetic fields of the magnet member 24 acts on the Hall sensor 33, and the Hall sensor 33 causes the circuit board 31 to be shut off. The circuit board 31 controls function keys and background lights to be shut off. Due to the magnetic fields of the magnet member 24 acts on the Hall sensor 33, the background lights remain shut even if the second body 30 is opened to a short distance relative to the first body 20.

When the second body 30 is opened to a long distance relative to the first body 20, the Hall sensor 70 is no longer affected by the magnetic fields of the magnet member 24, thus the circuit board 31 is conducted. Accordingly, the background lights illuminate, and the user may operate the sliding type mobile phone 100.

In an alternative embodiment, the Hall sensor 33 may be disposed in the first body 20. Accordingly, the magnet member 24 is disposed in the second body 30. When the first body 20 is closed relative to the second body 30, the magnet member 24 is opposite to the Hall sensor 33. When the first body 20 is opened relative to the second body 30, the magnet member 24 is far away from the Hall sensor 33.

The magnet member 24 is a necessary part in the portable electronic device, such as the speaker, thereby omitting the added component, such as the magnet 142. The portable electronic device will save a space of the magnet 142 occupied, thereby satisfying requirements in miniaturization for portable electronic device.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable electronic device, comprising:
a first body having a magnet member mounted thereon;
a second body slidably assembled on the first body and including a Hall sensor mounted thereon;
wherein the magnet member acts on the Hall sensor when the first body is moved relative to the second body, thereby switching the portable electronic device to a work mode when the Hall sensor faces to the magnet member or a power save mode when the Hall sensor is spaced away from the magnet member.

2. The portable electronic device as claimed in claim 1, wherein the magnet member includes a main body and a sound-absorbing part attached to the main body, the first body including a sound hall portion defining a plurality of holes therein, the sound-absorbing part adhered on periphery of the sound hall portion.

3. The portable electronic device as claimed in claim 2, wherein the second body has a circuit board, the Hall sensor is secured on the circuit board and faces to the magnet member.

4. The portable electronic device as claimed in claim 2, wherein the magnet member is a speaker.

5. A portable electronic device, comprising:
a first body having a magnet member mounted thereon;
a second body slidably assembled on the first body and including a Hall sensor mounted thereon
wherein the magnet member acts on the Hall sensor when the first body is moved relative to the second body, thereby switching the portable electronic device to a work mode when the Hall sensor faces the magnet member or a power save mode when the Hall sensor is spaced away from the magnet member.

6. The portable electronic device as claimed in claim 5, wherein the magnet member includes a main body and a sound-absorbing part attached to the main body, the first body including a sound hall portion defining a plurality of holes therein, the sound-absorbing part adhered on periphery of the sound hall portion.

7. The portable electronic device as claimed in claim 6, wherein second body has a circuit board, the Hall sensor is secured on the circuit board and faces to the magnet member.

8. The portable electronic device as claimed in claim 5, wherein the magnet member is a speaker.
